(19) United States
(12) Patent Application Publication
(10) Pub. No.: US 2013/0087251 A1
(43) Pub. Date: Apr. 11, 2013

(54) THERMOELECTRIC ALLOY MATERIAL AND THERMOELECTRIC ELEMENT

(71) Applicants: Yion-Ni Liu, Hsinchu City (TW); Chia-Cheng Hsu, Changhua County (TW); Chia-Chang Shih, Taichung City (TW); Ruoh-Huey Uang, Hsinchu County (TW)

(72) Inventors: Yion-Ni Liu, Hsinchu City (TW); Chia-Cheng Hsu, Changhua County (TW); Chia-Chang Shih, Taichung City (TW); Ruoh-Huey Uang, Hsinchu County (TW)

(73) Assignee: INDUSTRIAL TECHNOLOGY RESEARCH INSTITUTE, Hsinchu (TW)

(21) Appl. No.: 13/489,461

(22) Filed: Jun. 6, 2012

(30) Foreign Application Priority Data
Oct. 6, 2011 (TW) 100136273
Apr. 24, 2012 (TW) 101114572

(51) Int. Cl. H01L 35/20; C22C 45/00; C22C 30/04; C22C 30/02

(52) U.S. Cl. 148/403; 420/581

(57) ABSTRACT

A thermoelectric alloy material and thermoelectric element are provided, wherein the thermoelectric alloy material includes a Half-Heusler (HH) composition as matrix. The thermoelectric alloy material is represented by following formula (I):

(Zrₐ₁Hf_{b1})x(Fe_{c1}Co_{d1})y(Sbₑ₁Sn_{f1})z (I)

In the formula (I), 0<a1<1, 0<b1<1, 0<c1<1, 0<d1<1, 0<e1<1, 0<f1<1, a1+b1=1, c1+d1=1, e1+f1=1, c1≦f1, and 0.25≦x, y, z≦0.35.

### CROSS-REFERENCE TO RELATED APPLICATION

This application claims the priority benefits of Taiwan application serial no. 100136273, filed on Oct. 6, 2011, and Taiwan application serial no. 101114572, filed on Apr. 24, 2012. The entirety of each of the above-mentioned patent applications is hereby incorporated by reference herein and made a part of specification.

### TECHNICAL FIELD

The disclosure relates to a thermoelectric alloy material and a thermoelectric element capable of enhancing electrical conductivity.

### BACKGROUND

With the recent trend in energy saving and carbon reduction, advanced countries all devoted into the development of environment protection technology such as power generation from wind power, hydraulic power, biomass energy, and solar energy. Currently, most of daily equipments such as vehicles, appliance and the like generate waste heat. Accordingly, effective utilization of renewable energy can help alleviating global warming.

Since the element constituted by thermoelectric material can be converted between thermal energy and electrical energy directly and the thermoelectric module constituted by the element does not require a dynamic component, is reliable and quiet, and does not require combustion, the thermoelectric module is thus environmental friendly. Moreover, the thermoelectric module is light, compact, and portable and has consequently become one of the targets in developing green energy technology as those in U.S. Pat. No. 7,849,909 and U.S. Pat. No. 7,851,692.

### SUMMARY

A thermoelectric alloy material capable of improving electrical conductivity and thermoelectric property is introduced herein.

A thermoelectric element having a P-type material capable of enhancing electrical conductivity is introduced herein.

A thermoelectric alloy material is introduced herein. The thermoelectric alloy material includes a Half-Heusler (HH) composition as a matrix. The thermoelectric alloy material is represented by the following formula (I):

(Zrₐ₁Hf_{b1})x(Fe_{c1}Co_{d1})y(Sbₑ₁Sn_{f1})z (I)

In formula (I), 0<a1<1, 0<b1<1, 0<c1<1, 0<d1<1, 0<e1<1, 0<f1<1, a1+b1=1, c1+d1=1, e1+f1=1, c1≦f1, and 0.25≦x, y, z≦0.35.

A thermoelectric element including the thermoelectric alloy material as a P-type material therein is introduced herein.

In light of the foregoing, the thermoelectric material in the disclosure includes a heterogeneous composition generated from the thermoelectric alloy material such as Fe so that an HH thermoelectric matrix (e.g. ZrHfCoSbSn) forms an interface with high conductivity (e.g. a heterogeneous structure in a FeSn phase), thereby enhancing the overall conductivity and thermoelectric property of the thermoelectric alloy material.

Several exemplary embodiments accompanied with figures are described in detail below to further describe the disclosure in details.

### BRIEF DESCRIPTION OF THE DRAWINGS

The disclosure contains at least one color photograph. Copies of the disclosure publication with the color photographs will be provided by the Patent & Trademark Office upon request and payment of the necessary fee. The accompanying drawings are included to provide further understanding, and are incorporated in and constitute a part of this specification. The drawings illustrate exemplary embodiments and, together with the description, serve to explain the principles of the disclosure.

FIG. 1 is a schematic diagram illustrating a crystal phase of a thermoelectric alloy material according to an exemplary embodiment.

FIG. 2 is a sketch diagram illustrating a thermoelectric element according to another exemplary embodiment.

FIG. 3 is an XRD analysis graph of a thermoelectric alloy material in experiment 1.

FIG. 4 is an SEM photo of a thermoelectric alloy material in experiment 2.

FIG. 5 is a color photo of mapping micrograph of FIG. 4 for illustrating Fe composition in the thermoelectric alloy material in experiment 2.

FIG. 6 is a color photo of mapping micrograph of FIG. 4 for illustrating Sn composition in the thermoelectric alloy material in experiment 2.

### DETAILED DESCRIPTION OF DISCLOSED EMBODIMENTS

A thermoelectric alloy material is introduced in the disclosure. The thermoelectric alloy material includes a Half-Heusler (HH) composition as a matrix. The thermoelectric alloy material is represented by the following formula (I):

(Zrₐ₁Hf_{b1})x(Fe_{c1}Co_{d1})y(Sbₑ₁Sn_{f1})z (I)

In formula (I), 0<a1<1, 0<b1<1, 0<c1<1, 0<d1<1, 0<e1<1, 0<f1<1, a1+b1=1, c1+d1=1, e1+f1=1, c1≦f1, and 0.25≦x, y, z≦0.35.

FIG. 1 is a schematic diagram illustrating a crystal phase of a thermoelectric alloy material according to an exemplary embodiment. In FIG. 1, an HH composition 102 in a thermoelectric alloy material 100 occupies about 80 volume percentage (vol. %) to 95 vol. % of the entire thermoelectric alloy material 100. On the other hand, a heterogeneous composition 104 generated from the thermoelectric alloy material 100 may occupy about 5 vol. % to 20 vol. % of the entire thermoelectric alloy material 100, wherein the heterogeneous composition 104 may be phase or amorphous. Alternatively, the heterogeneous composition 104 may be a mixture of phase and amorphous. In the present embodiment, the so-called heterogeneous composition refers to having a composition different from the HH structure, such as a Fe-Sn composition which specifically includes a Fe₃Sn₂, Fe₅Sn₃, FeSn, FeSn₂ and combination thereof. Moreover, the crystal structure of the Fe-Sn composition may be phase or amorphous in thermoelectric alloy material. When the heterogeneous composition is the Fe-Sn, an atomic percentage of Fe therein ranges from 30% to 70%, an atomic percentage of Sn in ranges from 30% to 70%, and an atomic weight ratio of Fe and Sn ranges from 0.3 to 2.4, preferably from 0.3 to 1.7. In addition, a portion of Fe in the Fe-Sn composition is replaced by at least one element selected from a group consisting of Al, Hf, and Zr so as to form an Al-Sn composition, an Hf-Sn composition, or a Zr-Sn composition. Since the exemplary embodiment includes Fe and does not contain elements, such as titanium (Ti), indium (In), copper (Cu), nickel (Ni), niobium (Nb), tantalum (Ta) that are highly active and inhibit the formation of the Fe-Sn composition, an interface with high conductivity (i.e. the heterogeneous composition: Fe-Sn composition) can be formed between the HH composition to enhance the overall conductivity and thermoelectric property of the thermoelectric alloy material.

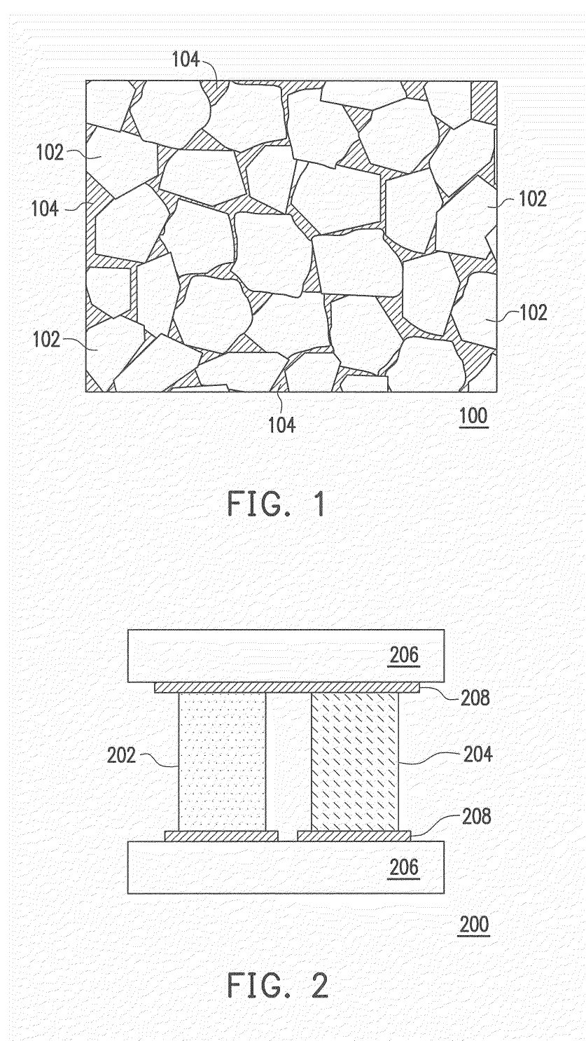

FIG. 2 is a sketch diagram illustrating a thermoelectric element according to another exemplary embodiment. In FIG. 2, a thermoelectric element 200 includes an N-type semiconductor 202 and a P-type semiconductor 204. Also, the thermoelectric element 200 usually includes a substrate 206 and an electrode 208. In this figure, a material of the P-type semiconductor 204 is the thermoelectric alloy material of above exemplary embodiment.

In the following, several examples are shown to illustrate the disclosure.

### EXAMPLE

### Experiment 1

### Synthesis of (Zr_{0.5}Hf_{0.5})_{0.33}(Fe_{0.1}Co_{0.9})_{0.33}(Sn_{0.15}Sb_{0.85})_{0.33}

Step 1: Prepare for a thermoelectric alloy material. In detail, elements Zr, Hf, Co, Sn, Sb, and Fe in an HH alloy are rinsed and then dispensed according a composition displayed in Table 1.

Step 2: Perform a high temperature melting reaction to the composition in the step 1, generally the reaction is heated to 1400° C. or above for melting the elements and to form a solid solution.

Step 3: Rapid solidification ,the cooling rate is selected a range form 20° C./sec to 100° C./sec.

### Experiment 2

### Synthesis of (Zr_{0.5}Hf_{0.5})_{0.33}(Fe_{0.1}Co_{0.9})_{0.33}(Sn_{0.2}Sb_{0.8})_{0.33}

Perform the same steps in experiment 1, the only difference lies in the amounts of the compositions.

### Experiment 3

### Synthesize (Zr_{0.5}Hf_{0.5})_{0.33}(Fe_{0.2}Co_{0.8})_{0.33}(Sn_{0.3}Sb_{0.7})_{0.33}

Perform the same steps in experiment 1, the only difference lies in the amounts of the compositions.

### Comparison 1

### Synthesis of (Zr_{0.5}Hf_{0.5})_{0.33}(Co_{1.0})_{0.33}(Sn_{0.15}Sb_{0.85})_{0.33}

Perform the same steps in experiment 1, the differences are that the composition herein does not include Fe and the amounts of the compositions are different.

### Comparison 2

### Synthesis of (Zr_{0.5}Hf_{0.5})_{0.33}(Co_{1.0})_{0.33}(Sn_{0.2}Sb_{0.8})_{0.33}

Perform the same steps in experiment 1, the differences are that the composition herein does not include Fe and the amounts of the compositions are different.

### Comparison 3

### Synthesis of (Zr_{0.5}Hf_{0.5})_{0.33}(Co_{1.0})₃₃(Sn_{0.3}Sb_{0.7})_{0.33}

Perform the same steps in experiment 1, the differences are that the composition herein does not include Fe and the amounts of the compositions are different.

### Measurement

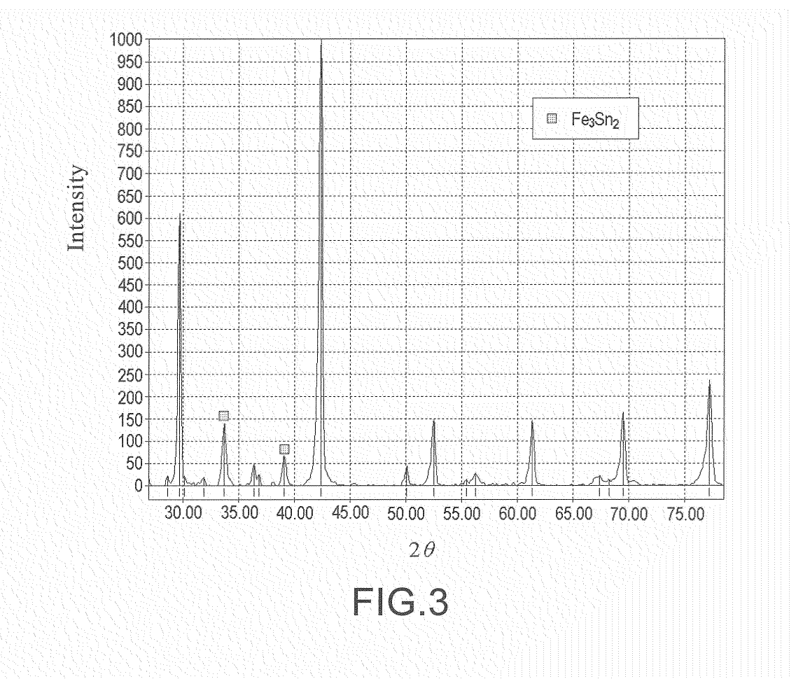

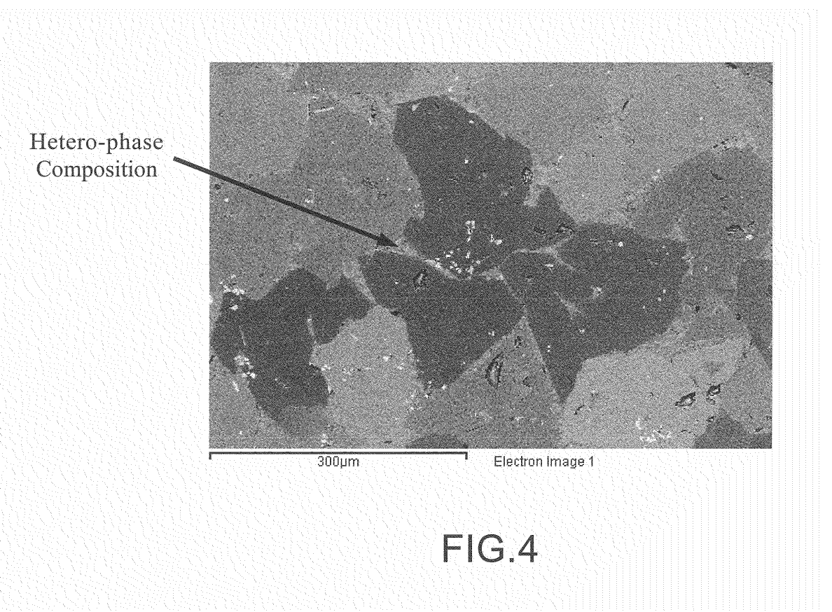

The thermoelectric alloy materials formed undergo property measurement and analysis including an XRD analysis, an SEM analysis, and a thermoelectric property analysis. FIG. 3 is an XRD analysis graph of experiment 1, where a Fe₃Sn₂ composition is shown. FIG. 4 is an SEM photo of experiment 2, where a heterogeneous composition similar to that shown in FIG. 1 is displayed between the HH composition.

The result of the thermoelectric property analysis is listed in Table 1.

TABLE 1

| | | | | | | | Electrical |
|---|---|---|---|---|---|---|---|
| | Composition (Unit: at %) | | | | | | conductivity |
| | Zr | Hf | Fe | Co | Sn | Sb | (s/cm) |
| Comparison 1 | 0.5 | 0.5 | — | 1 | 0.15 | 0.85 | 1270 |
| Comparison 2 | 0.5 | 0.5 | — | 1 | 0.2 | 0.8 | 1332.3 |
| Comparison 3 | 0.5 | 0.5 | — | 1 | 0.3 | 0.7 | 760.5 |
| Experiment 1 | 0.5 | 0.5 | 0.1 | 0.9 | 0.15 | 0.85 | 1405.5 |
| Experiment 2 | 0.5 | 0.5 | 0.1 | 0.9 | 0.2 | 0.8 | 2285.7 |
| Experiment 3 | 0.5 | 0.5 | 0.2 | 0.8 | 0.3 | 0.7 | 1730 |

As depicted in Table 1, the thermoelectric alloy material in the disclosure contains a suitable amount of Fe and thus has superior conductivity comparing to those thermoelectric materials not containing Fe.

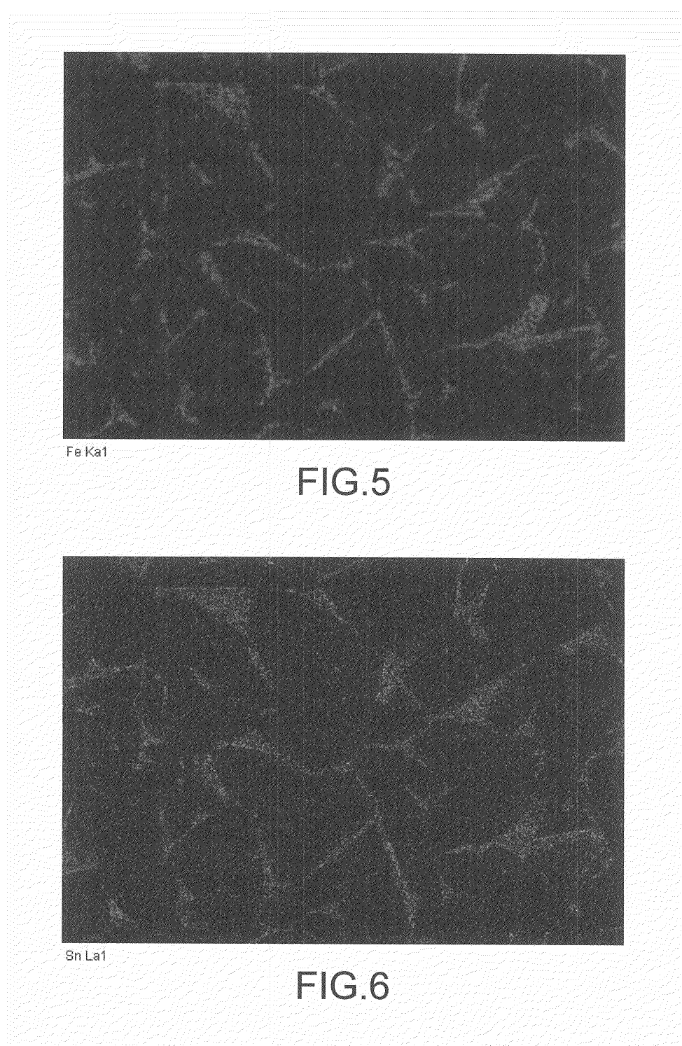

FIG. 5 is a color photo of mapping micrograph of FIG. 4, where the red portion represents the distribution of Fe compositions and the block portion represents HH compositions. In FIG. 5, it is clear that the Fe compositions are uniformly distributed in grain boundary of the HH compositions.

FIG. 6 is another color photo of mapping micrograph of FIG. 4, where the blue-green portion represents the distribution of Sn compositions and the block portion represents HH compositions. In FIG. 6, it is obvious that the Sn compositions are uniformly distributed in grain boundary of the HH compositions.

The result of elemental analysis from the thermoelectric alloy material shown in FIGS. 5-6 is listed in Table 2.

TABLE 2

| Element | Weight % | Atomic % |
|---|---|---|
| FeK | 0.16 | 0.30 |
| CoK | 16.80 | 30.44 |
| ZrL | 14.59 | 17.08 |
| SnL | 4.77 | 4.29 |
| SbL | 35.14 | 30.81 |
| HfM | 28.54 | 17.07 |
| Totals | 100.00 | |

In summary, the disclosure utilizes the addition of Fe to synthesize the thermoelectric alloy material with the heterogeneous composition, and the heterogeneous composition has high conductivity, does not have the HH structure, and is generated caused by the supersaturated precipitation. As a consequence, the electrical conductivity of the overall material is increased and an interface is formed/evenly distributed in-situ in the fabrication, thereby enhancing the electrical conductivity of the thermoelectric alloy material effectively.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A thermoelectric alloy material, is represented by the following formula (I):
(Zrₐ₁Hf_{b1})x(Fe_{c1}Co_{d1})y(Sbₑ₁Sn_{f1})z (I)
In formula (I), 0<a1<1, 0<b1<1, 0<c1<1, 0<d1<1, 0<e1<1, 0<f1<1, a1+b1=1, c1+d1=1, e1+f1=1, c1≦f1, and 0.25≦x, y, z≦0.35; and
the thermoelectric alloy material comprises a Half-Heusler composition as a matrix.

2. The thermoelectric alloy material as claimed in claim 1, further comprising an heterogeneous composition generated from the thermoelectric alloy material, wherein the heterogeneous composition is phase, amorphous, or a mixture of phase and amorphous.

3. The thermoelectric alloy material as claimed in claim 2, wherein based on a volume of the entire thermoelectric alloy material, a volume percentage of the Half-Heusler composition is from 80 vol. % to 95 vol. % and a volume percentage of the heterogeneous composition is from 5 vol. % to 20 vol. %.

4. The thermoelectric alloy material as claimed in claim 2, wherein the heterogeneous composition is a Fe-Sn composition.

5. The thermoelectric alloy material as claimed in claim 4, wherein a portion of Fe in the heterogeneous composition is replaced by at least one element selected from a group consisting of Al, Hf, and Zr.

6. The thermoelectric alloy material as claimed in claim 4, wherein an atomic percentage of Fe in the heterogeneous composition ranges from 30% to 70%.

7. The thermoelectric alloy material as claimed in claim 4, wherein an atomic percentage of Sn in the heterogeneous composition ranges from 30% to 70%.

8. The thermoelectric alloy material as claimed in claim 7, wherein an atomic weight ratio of Fe and Sn ranges from 0.3 to 2.4.

9. A thermoelectric element, comprising a thermoelectric alloy material as claimed in claim 1 as a P-type material in the thermoelectric element.

10. A thermoelectric element, comprising a thermoelectric alloy material as claimed in claim 2 as a P-type material in the thermoelectric element.

11. A thermoelectric element, comprising a thermoelectric alloy material as claimed in claim 3 as a P-type material in the thermoelectric element.

12. A thermoelectric element, comprising a thermoelectric alloy material as claimed in claim 4 as a P-type material in the thermoelectric element.
